(19) United States
(12) Patent Application Publication
(10) Pub. No.: US 2012/0112308 A1
(43) Pub. Date: May 10, 2012

(54) SEMICONDUCTOR DEVICE, SEMICONDUCTOR GROUP MEMBER AND SEMICONDUCTOR DEVICE MANUFACTURING METHOD

(75) Inventors: Tetsuo Matsuda, Ishikawa-ken (JP); Tomomi Imamura, Ishikawa-ken (JP)

(73) Assignee: Kabushiki Kaisha Toshiba, Tokyo (JP)

(21) Appl. No.: 13/238,617

(22) Filed: Sep. 21, 2011

(30) Foreign Application Priority Data
Nov. 5, 2010 (JP) 2010-248867

(51) Int. Cl. H01L 25/00; H01L 21/66; H01L 21/78

(52) U.S. Cl. 257/503; 438/460; 438/14; 257/E25.001; 257/E21.599; 257/E21.529

(57) ABSTRACT

According to one embodiment, a semiconductor device includes a device portion, a first electrode portion, a second electrode portion and a protruding portion. The device portion is provided on a substrate. The first electrode portion is provided on the device portion and is electrically contacted with the device portion. The second electrode portion is provided on the device portion separated from the first electrode portion, and electrically contacted with the device portion. The protruding portion is provided on the device portion and protrudes outward from a peripheral portion of the first electrode portion and the second electrode portion.

### CROSS-REFERENCE TO RELATED APPLICATIONS

This application is based upon and claims the benefit of priority from the prior Japanese Patent Application No. 2010-248867, filed on Nov. 5, 2010; the entire contents of which are incorporated herein by reference.

### FIELD

Embodiments described herein relate generally to a semiconductor device, a semiconductor group member and a semiconductor device manufacturing method.

### BACKGROUND

The on-resistance of transistor or diode is an indicator of how much current is allowed to pass in the on state. On-resistance is subject to substantial variations and so, in the design and manufacture of semiconductor devices, a set of mask patterns (mask set) with various differing specifications is prepared to match the specifications required by the customer. The preparation of mask sets to meet customer requirements in this way is a laborious part of the design and manufacture of semiconductor devices.

### BRIEF DESCRIPTION OF THE DRAWINGS

FIG. 1A to FIG. 5B are schematic plan views illustrating semiconductor devices according to a first embodiment;

FIG. 6 and FIG. 7 are schematic plan views illustrating semiconductor group members according to a second embodiment;

FIGS. 8 to 16 are schematic views illustrating manufacturing methods according to a third embodiment;

FIGS. 17A and 17B are schematic plan views illustrating a form of electrode portions;

FIG. 18 to FIG. 19C are schematic plan views illustrating a manufacturing method according to a fourth embodiment;

FIG. 20 is a schematic plan view illustrating a semiconductor module that is an example of a semiconductor device according to a fifth embodiment; and

FIG. 21 is a schematic plan view for describing an example of another connecting member.

### DETAILED DESCRIPTION

In general, according to one embodiment, a semiconductor device includes a device portion, a first electrode portion, a second electrode portion and a protruding portion. The device portion is provided on a substrate. The first electrode portion is provided on the device portion. The first electrode portion is electrically contacted with the device portion. The second electrode portion is provided on the device portion separated from the first electrode portion. The second electrode portion is electrically contacted with the device portion. The protruding portion is provided on the device portion and protrudes outward from a peripheral portion of the first electrode portion and the second electrode portion.

Various embodiments will be described hereinafter with reference to the accompanying drawings.

Note that the drawings are schematic or conceptual in nature, and relationships between thicknesses and widths of each portion, ratios between sizes of portions and the like are not therefore necessarily identical to the actual relationships and ratios. Also, even where identical portions are depicted, dimensions and ratios may appear differently depending on the drawing.

Further, in the drawings and specification of this application, the same numerals are applied to elements that have already appeared in the drawings and been described, and repetitious detailed descriptions of such elements are omitted.

### First Embodiment

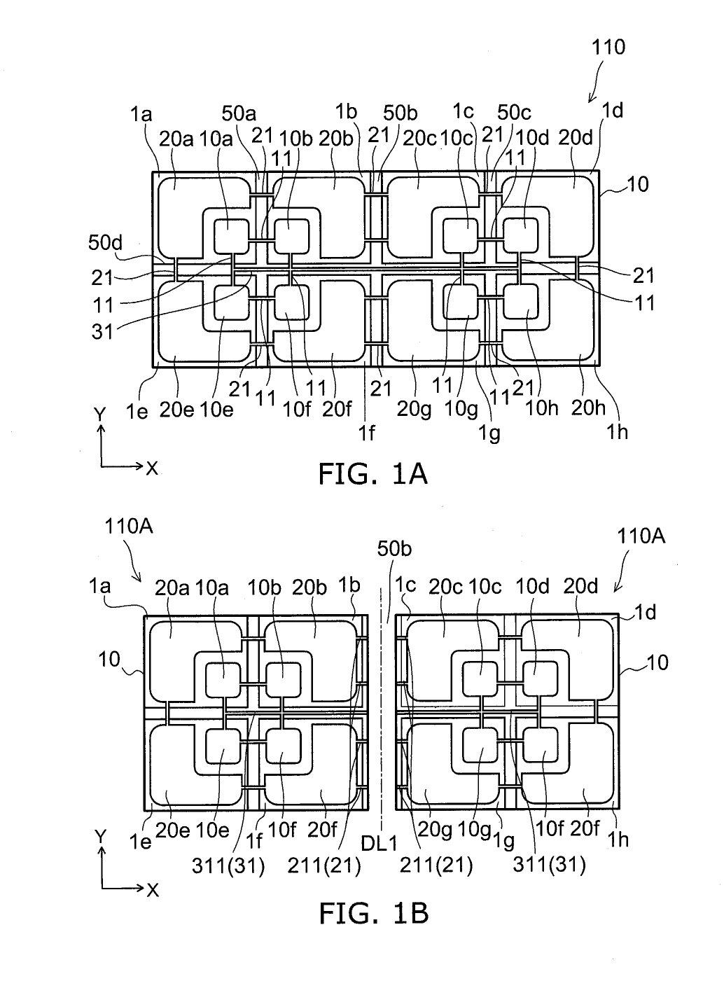

FIG. 1A to FIG. 5B are schematic plan views illustrating semiconductor devices according to a first embodiment.

FIG. 1A to FIG. 5B illustrate a semiconductor device 110 and semiconductor devices 110A to 110E according to the first embodiment.

First, the semiconductor device 110 illustrated in FIG. 1A will be described. As illustrated in FIG. 1A, the semiconductor device 110 includes a substrate 10, a plurality of device portions 1a to 1h, first electrode portions 10a to 10h, second electrode portions 20a to 20h, first connecting portions 11, and second connecting portions 21.

The substrate 10 is a silicon wafer that has been cut into rectangular pieces. The plurality of device portions 1a to 1h is formed on the substrate 10. Here, the plurality of device portions 1a to 1h is also collectively referred to simply as a device portion 1. The device portion 1 is a functioning device such as a MOSFET (Metal Oxide Semiconductor Field Effect Transistor), IGBT (Insulated Gate Bipolar Transistor), a diode, or the like. The device portion 1 is formed using a wafer process.

The semiconductor device 110 illustrated in FIG. 1A is, for example, provided with the eight device portions 1a to 1h.

Among the device portions 1a to 1h, a row of the four device portions 1a to 1d along an X direction and a row of the four device portions 1e to 1h along the X direction (first direction) are aligned along a Y direction (second direction perpendicular to the X direction). In the description below, “a” device portions 1 are arranged along the X direction and “b” device portions 1 are arranged along the Y direction to give an “a×b” semiconductor device. The “a” shows the number of the device portions along the X direction. The “b” shows the number of the device portions along the Y direction. For example, the semiconductor device 110 illustrated in FIG. 1A is a 4×2 semiconductor device 110.

In the 4×2 semiconductor device 110, isolations 50a to 50d are provided between the eight device portions 1a to 1h. The isolation 50a is provided between the device portions 1a and 1e, and between the device portions 1b and 1f. The isolation 50b is provided between the device portions 1b and 1f, and between the device portions 1c and 1g. The isolation 50c is provided between the device portions 1c and 1g, and between the device portions 1d and 1h. The isolation 50d is provided between the device portions 1a and 1d, and between the device portions 1e and 1h. The isolations 50a to 50d are selected as dividing lines (dicing lines) on the substrate 10 as required.

A first electrode portion 10a is provided on the device portion 1a. A first electrode portion 10b is formed on the device portion 1b. Similarly, first electrode portions 10c to 10h are formed on device portions 1c to 1h, respectively.

The first electrode portions 10a to 10h are electrical contacted with the device portions 1a to 1h, respectively. A second electrode portion 20a is provided on the device portion 1a. A second electrode portion 20b is provided on the device portion 1b. Similarly, the second electrode portions 20c to 20h are formed on the device portions 1c to 1h, respectively.

The second electrode portions 20a to 20h are electrically contacted with the device portions 1a to 1h, respectively.

Further, the second electrode portions 20a to 20h provided so as to be separated from the first electrode portions 10a to 10h.

Here, when the device portion 1 is a MOSFET, the first electrode portions 10a to 10h and the second electrode portions 20a to 20h are also used as electrode pads to which external connecting members such as bonding wires are connected. The first electrode portions 10a to 10h are, for example, electrode pads electrically contacted with gate electrodes, and the second electrode portions 20a to 20h are, for example, electrode pads electrically contacted with source electrodes. Note that the drain electrode, which is not illustrated in the drawings, is electrically contacted with an electrode formed on a back face of the substrate 10.

The first connecting portions 11 connect the adjacent first electrode portions of the first electrode portions 10a to 10h. The first connecting portions 11 are formed bridging the isolations (any of isolations 50a to 50d) provided between adjacent first electrode portions.

In the semiconductor device 110 illustrated in FIG. 1A, the first connecting portion 11 that connects the first electrode portions 10a and 10b, and the first connecting portion 11 that connects the first electrode portions 10e and 10f are formed bridging the isolation 50a.

Further, the first connecting portion 11 that connects the first electrode portions 10c and 10d, and the first connecting portion 11 that connects the first electrode portions 10g and 10h are formed bridging the isolation 50c.

Further, the first connecting portion 11 that connects the first electrode portions 10a and 10e, the first connecting portion 11 that connects the first electrode portions 10b and 10f, the first connecting portion 11 that connects the first electrode portions 10c and 10g, and the first connecting portion 11 that connects the first electrode portions 10d and 10h are formed bridging the isolation 50d.

The first connecting portions 11 may be provided integrally in a same material as the first electrode portions 10a to 10h or provided separately from the first electrode portions 10a to 10h. In the semiconductor device 110 illustrated in FIG. 1A, the first connecting portions 11 and the first electrode portions 10a to 10h are integrally provided.

The second connecting portions 21 connect adjacent second electrode portions of the second electrode portions 20a to 20h. The second connecting portions 21 are formed bridging the isolations (any of isolations 50a to 50d) provided between adjacent second electrode portions.

In the semiconductor device 110 illustrated in FIG. 1A, the second connecting portion 21 that connects the second electrode portions 20a and 20b, and the second connecting portion 21 that connects the second electrode portions 20e and 20f are formed bridging the isolation 50a.

Further, the second connecting portion 21 that connects the second electrode portions 20b and 20c, and the second connecting portion 21 that connects the second electrode portions 20f and 20g are formed bridging the isolation 50b.

Further, the second connecting portion 21 that connects the second electrode portions 20c and 20d, and the second connecting portion 21 that connects the second electrode portions 20g and 20h are formed bridging the isolation 50c.

Further, the second connecting portion 21 that connects the second electrode portions 20a and 20e, and the second connecting portion 21 that connects the second electrode portions 20d and 20h are formed bridging the isolation 50d.

The second connecting portions 21 may be provided integrally in a same material as the second electrode portions 20a to 20h or provided separately from the second electrode portions 20a to 20h. In the semiconductor device 110 illustrated in FIG. 1A, the second connecting portions 21 and the second electrode portions 20a to 20h are integrally provided.

Further, in the semiconductor device 110, the first electrode portions 10a, 10b, 10e and 10f provided in the 2×2 device portions 1 are positioned near the isolations 50a and 50d.

Further, the first electrode portions 10c, 10d, 10g and 10h provided in the 2×2 device portions 1 are also positioned near the isolations 50c and 50d.

In the semiconductor device 110, a conducting portion 31 is provided between the first connecting portions 11 that connect the first electrode portions 10a, 10b, 10e and 10f, and the first connecting portions 11 that connect the first electrode portions 10c, 10d, 10g and 10h.

Here, the conducting portion 31 is one of the first connecting portions 11. Thus, the conducting portion 31 bridges the isolation 50b provided between the device portion 1b and the device portion is and connects the adjacent first electrode portions 10b and 10c. Similarly, the conducting portion 31 bridges the isolation 50b provided between the device portion 1f and the device portion 1g and connects the adjacent first electrode portions 10f and 10g.

The conducting portion 31 is formed along the isolation 50d. As a result of the conducting portion 31, the group of first electrode portions 10a, 10b, 10e and 10f are electrically contacted with the group of first electrode portions 10c, 10d, 10g and 10h.

In the eight device portions 1a to 1h with the 4×2 configuration illustrated in FIG. 1A, each of the first electrode portions 10a to 10h are electrically contacted by the first connecting portions 11 and the conducting portion 31.

Further, each of the second electrode portions 20a to 20h are electrically contacted by the second connecting portions 21.

Consequently, the semiconductor device 110 has a structure in which the eight device portions 1a to 1h are grouped. Thus, if the device portions 1 are MOSFETs, for example, the first electrode portions 10a to 10h are electrically contacted with, for instance, a gate electrode of the eight device portions 1a to 1h function as a single gate electrode portion (a gate electrode pad, for instance), and the second electrode portions 20a to 20h are electrically contacted with, for example, a source electrode function as a single source electrode portion (a source electrode pad, for instance).

As a result, in the eight device portions 1a to 1h, the first electrode portions 10a to 10h and the second electrode portions 20a to 20h have electrical commonality, respectively.

A semiconductor device 110A illustrated in FIG. 1B is a 2×2 configuration resulting from dividing the 4×2 semiconductor device 110 illustrated in FIG. 1A.

Specifically, the semiconductor device 110A is formed by dividing the substrate 10 using the isolation 50b of the 4×2 semiconductor device 110 illustrated in FIG. 1A as a dicing line DL1. In the example illustrated in FIG. 1, the 2×2 semiconductor device 110A with the device portions 1a, 1b, 1e and 1f and the 2×2 semiconductor device 110A with the device portions 1c, 1d, 1g and 1h are formed by dividing the 4×2 semiconductor device 110 using the isolation 50b as the dicing line DL1.

When the substrate 10 is divided using the dicing line DL1, the second connecting portions 21 bridging the isolation 50b are cut. When the second connecting portions 21 are cut, protruding portions 211 extending outwards from a periphery of each of the second electrode portions 20b, 20c, 20f and 20g are formed.

Further, when the substrate 10 is divided using the dicing line DL1, the conducting portion 31 bridging the isolation 50b is also cut. When the conducting portion 31 is cut, protruding portions 311 are formed.

The semiconductor device 110A according to this embodiment is the same as the 4×2 semiconductor device 110 in terms of the configuration of the device portions 1, the first electrode portions 10a to 10h and the second electrode portions 20a to 20h, thus allowing product development to be performed on 2×2 configurations.

In other words, besides forming the 4×2 semiconductor device 110, the 2×2 semiconductor device 110A can be formed with the same mask pattern used to form the device portions 1, the first electrode portions 10a to 10h and the second electrode portions 20a to 20h, by simply changing the dicing line.

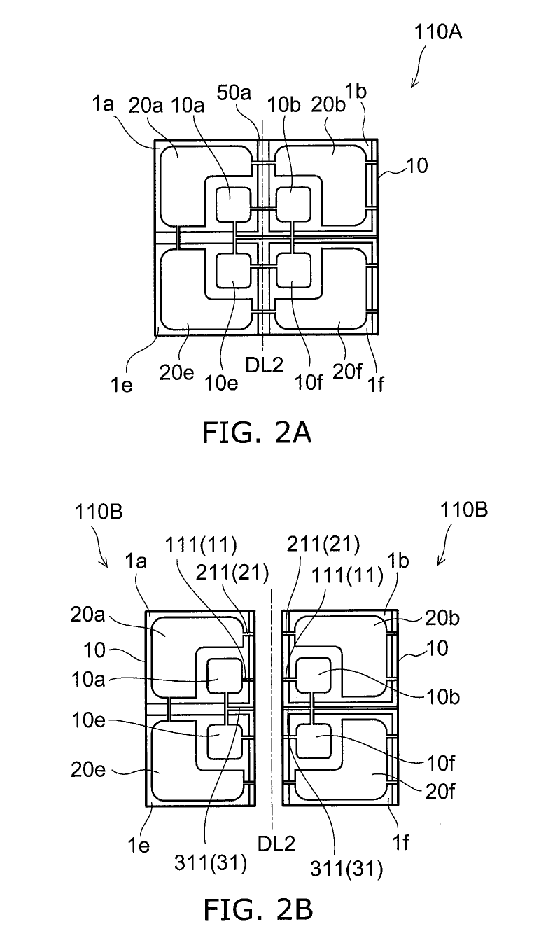

FIGS. 2A and 2B are schematic plan views illustrating a semiconductor device 110B.

The semiconductor device 110B is formed by dividing, for example, the semiconductor device 110A. Specifically, when the substrate 10 of the 2×2 semiconductor 110A illustrated in FIG. 2A is divided using the isolation 50a as a dicing line DL2, the 1×2 semiconductor devices 110B illustrated in FIG. 2B are formed.

In the example illustrated in FIG. 2, when the substrate 10 of the 2×2 semiconductor device 110A illustrated in FIG. 2A is divided using the isolation 50a as a dicing line DL2, the 1×2 semiconductor device 110B with the device portions 1a and 1e and the 1×2 semiconductor device 110B with the device portions 1b and 1f are formed (see FIG. 2B).

When the substrate 10 is divided using the dicing line DL2, the second connecting portions 21 that bridge the isolation 50a are cut. When the second connecting portions 21 are cut, protruding portions 211 extending outwards from a periphery of each of the second electrode portions 20a, 20b, 20e and 20f are formed.

Further, when the substrate 10 is divided using the dicing line DL2, the first connecting portions 11 bridging the isolation 50a are cut. When the first connecting portions 11 are cut, protruding portions 111 extending outwards from a periphery of each of the first electrode portions 10a, 10b, 10e and 10f are formed. Further, when the substrate 10 is divided using the dicing line DL2, the conducting portion 31 bridging the isolation 50b is cut. When the conducting portion 31 is cut, protruding portions 311 are formed.

With the semiconductor device 1108 according to this embodiment, product development on the 1×2 semiconductor device 1106 can be carried out while retaining the same device portions 1, first electrode portions 10a to 10h and second electrode portions 20a to 20h as the 4×2 semiconductor device 110.

Specifically, by forming the semiconductor device 110A from the semiconductor device 110 and then forming the semiconductor device 1108 from the semiconductor device 110A, configurations of the first device portions 1, first electrode portions 10a to 10h, and second electrode portions 20a to 20h are same as the 4×2 semiconductor device 110, and so product development can be carried out on 2×2 and 1×2 configurations.

Note that although an example in which the semiconductor device 110A is divided to form the semiconductor device 1108 is described, the 1×2 semiconductor device 1106 may be formed directly by dividing the 4×2 semiconductor device 110 at each of the isolations 50a, 50b and 50c.

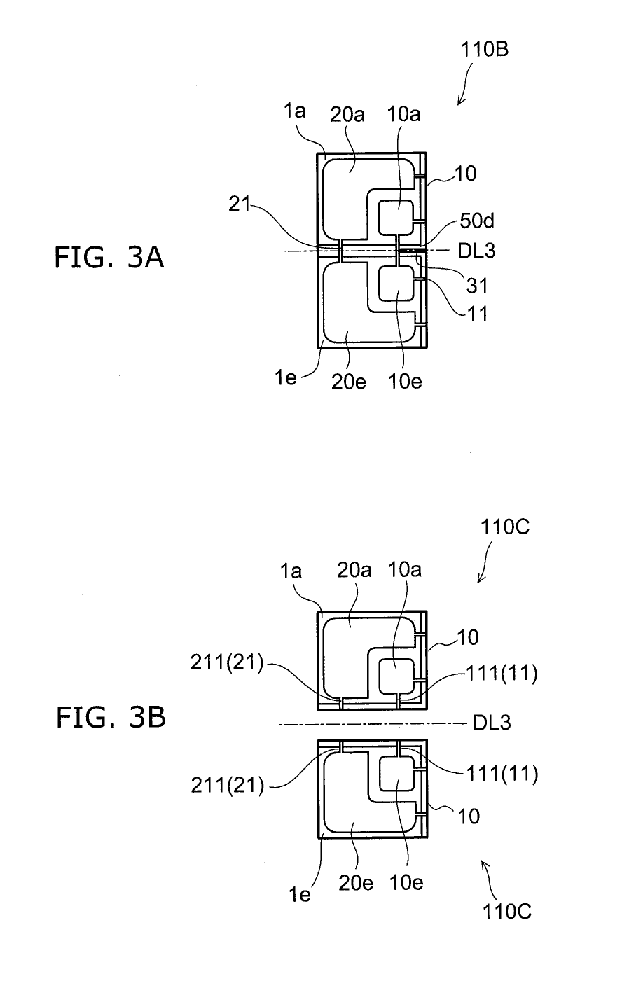

FIGS. 3A and 3B are schematic plan views illustrating a semiconductor device 110C.

The semiconductor device 110C is formed by dividing, for example, the semiconductor device 110B. Specifically, when the substrate 10 of the 1×2 semiconductor device 110B illustrated in FIG. 3A is divided using the isolation 50d as a dicing line DL3, the 1×1 semiconductor devices 110C illustrated in FIG. 3B are formed.

In the example illustrated in FIGS. 3A and 3B, when the 1×2 semiconductor device 110B illustrated in FIG. 3A is divided using the isolation 50d as the dicing line DL3, the 1×1 semiconductor device 110C with the device portion 1a and the 1×1 semiconductor device 110C with the device portion 1e are formed (see FIG. 3B).

When the substrate 10 is divided using the dicing line DL3, the second connecting portion 21 bridging the isolation 50d is cut. When the second connecting portion 21 is cut, protruding portions 211 extending outwards from a periphery of each of the second electrode portions 20a and 20e are formed. Further, when the substrate 10 is divided using the dicing line DL3, the first connecting portion 11 bridging the isolation 50d is cut. When the first connecting portion 11 is cut, protruding portions 111 extending outwards from a periphery of each of the first electrode portions 10a and 10e are formed. Further, when the substrate 10 is divided using the dicing line DL3, the conducting portion 31 provided along the isolation 50d is removed. If the conducting portion 31 is made narrower than a width of the cut by the dicing saw, the conducting portion 31 will be removed when the substrate 10 is diced along the direction of the conducting portion 31.

With the semiconductor device 110C according to this embodiment, product development on the 1×1 semiconductor device 110C can be carried out while retaining the same device portions 1, first electrode portions 10a to 10h and second electrode portions 20a to 20h as the 4×2 semiconductor device 110.

Specifically, by forming the semiconductor device 110A from the semiconductor device 110, further forming the semiconductor device 1108 from the semiconductor device 110A and then forming the semiconductor device 110C from the semiconductor device 1106, configurations of the first device portions 1, first electrode portions 10a to 10h, and second electrode portions 20a to 20h are same as the 4×2 semiconductor device 110, and so product development can be carried out on 2×2, 1×2 and 1×1 configurations. Note that although an example in which the semiconductor device 110B is divided to form the semiconductor device 110C is described, the 1×1 semiconductor device 110C may be formed directly by dividing the 4×2 semiconductor device 110 at each of the isolations 50a, 50b, 50c and 50d.

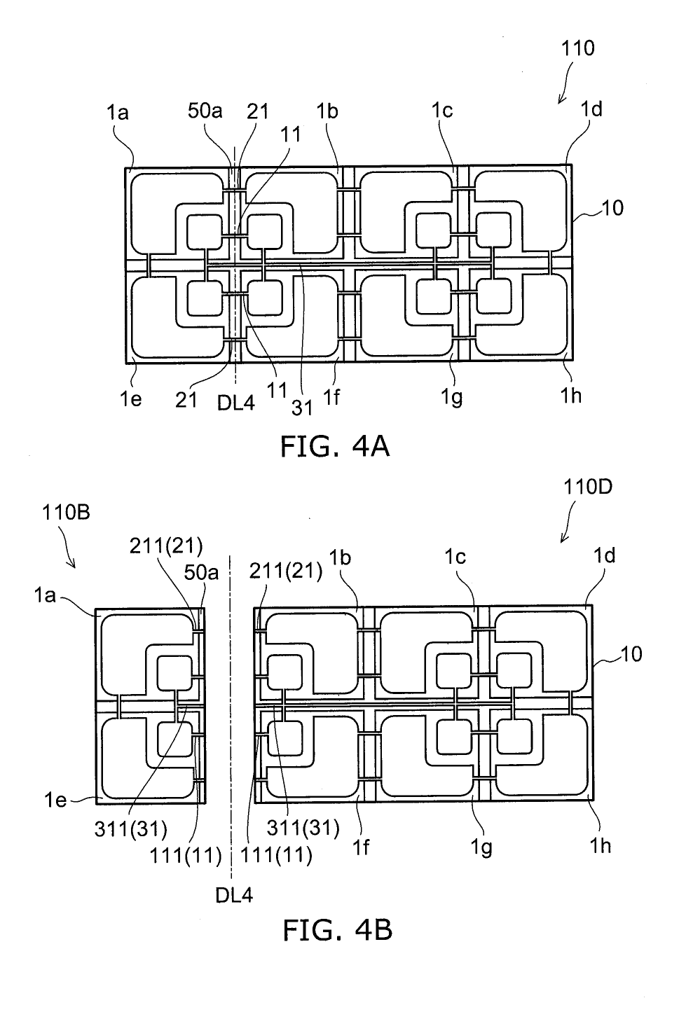

FIGS. 4A and 4B are schematic plan views illustrating a semiconductor device 110D.

The semiconductor device 110D is formed by dividing, for example, the semiconductor device 110. Specifically, when the substrate 10 of the 4×2 semiconductor device 110 illustrated in FIG. 4A is divided using the isolation 50a as a dicing line DL4, the 3×2 semiconductor device 110D and the 1×2 semiconductor device 1108 illustrated in FIG. 4B are formed.

In the example illustrated in FIGS. 4A and 4B, when the 4×2 semiconductor device 110 illustrated in FIG. 4A is divided using the isolation 50a as a dicing line DL4, the semiconductor device 110D with the device portions 1b, 1c, 1d, 1f, 1g and 1h and the 2×1 semiconductor device 1108 with the device portions 1a and 1e are formed (see FIG. 4B).

When the substrate 10 is divided using the dicing line DL4, the second connecting portions 21 that bridge the isolation 50a are cut. When the second connecting portions 21 are cut, protruding portions 211 extending outwards from a periphery of each of the second electrode portions 20a, 20b, 20e and 20f are formed.

Further, when the substrate 10 is divided using the dicing line DL4, the first connecting portions 11 bridging the isolation 50a are cut. When the first connecting portions 11 are cut, protruding portions 111 extending outwards from a periphery of each of the second electrode portions 10a, 10b, 10e and 10f are formed.

Further, when the substrate 10 is divided using the dicing line DL4, the conducting portion 31 bridging the isolation 50b is cut. When the conducting portion 31 is cut, protruding portions 311 are formed.

With the semiconductor device 110D according to this embodiment, product development on the 3×2 semiconductor device 110D and the 1×2 semiconductor device 110B can be carried out while retaining the same device portions 1, first electrode portions 10a to 10h and second electrode portions 20a to 20h as the 4×2 semiconductor device 110.

More specifically, the 3×2 semiconductor device 110D and the 1×2 semiconductor device 110B can be formed without changing the mask pattern used to form the device portions 1, the first electrode portions 10a to 10h and the second electrode portions 20a to 20h.

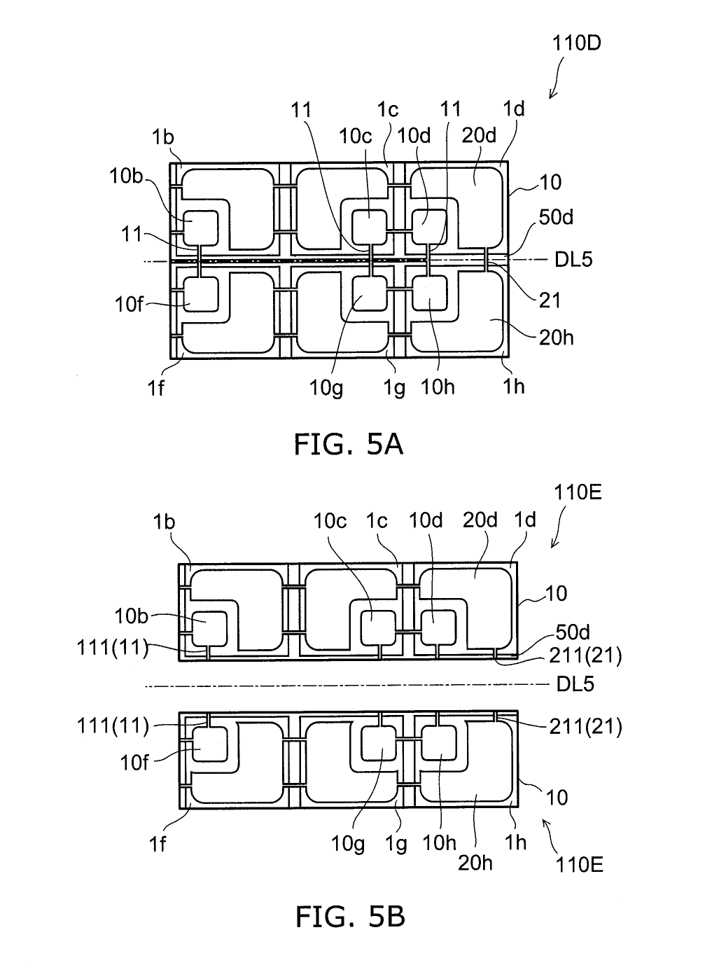

FIGS. 5A and 5B are schematic plan views illustrating a semiconductor device 110E.

The semiconductor device 110E is formed by dividing, for example, the semiconductor device 110D. Specifically, when the substrate 10 of the 3×2 semiconductor device 110D illustrated in FIG. 5A is divided using the isolation 50d as a dicing line DL5, the 3×1 semiconductor device 110E illustrated in FIG. 5B is formed.

In the example illustrated in FIGS. 5A and 5B, when the 3×2 semiconductor device 110D illustrated in FIG. 5A is divided using the isolation 50d as the dicing line DL5, the 3×1 semiconductor device 110E with the device portions 1b, 1c and 1d, and the 3×1 semiconductor device 110E with the device portions 1f, 1g and 1h are formed (see FIG. 5B).

When the substrate 10 is divided using the dicing line DL5, the second connecting portion 21 bridging the isolation 50d is cut. When the second connecting portion 21 is cut, protruding portions 211 extending outwards from a periphery of each of the second electrode portions 20d and 20h are formed. Further, when the substrate 10 is divided using the dicing line DL5, the first connecting portions 11 bridging the isolation 50d are cut. When the first connecting portions 11 are cut, protruding portions 111 extending outwards from a periphery of each of the second electrode portions 10b, 10c, 10d, 10f, 10g and 10h are formed.

Further, when the substrate 10 is divided using the dicing line DL5, the conducting portion 31 provided along the isolation 50d is removed. If the conducting portion 31 is made narrower than a width of the cut by the dicing saw, the conducting portion 31 will be removed when the substrate 10 is diced along the direction of the conducting portion 31.

Note that when the conducting portion 31 is removed, the first electrode portion 10b does not have electrical continuity with the first electrode portions 10c and 10d, and so electrical continuity is achieved by internal or external means using a connection-use conductor such as bonding wire, metal terminal, or the like.

The same applies to electrical continuity between the first electrode portion 10f and the first electrode portions 10g and 10h.

With the semiconductor device 110E according to this embodiment, product development on the 3×1 semiconductor device 110E can be carried out while retaining the same device portions 1, first electrode portions 10a to 10h and second electrode portions 20a to 20h as the 4×2 semiconductor device 110.

Specifically, by forming the semiconductor device 110D from the semiconductor device 110 and then forming the semiconductor device 110E from the semiconductor device 110D, the configurations of the first device portions 1, first electrode portions 10a to 10h, and second electrode portions 20a to 20h are same as the 4×2 semiconductor device 110, and so product development can be carried out on 3×2 and 3×1 configurations. In addition, the 1×2 semiconductor device 1108 is simultaneously formed.

Note that although an example in which the semiconductor device 110D is divided to form the semiconductor device 110E is described, the 3×1semiconductor device 110E may be formed directly by dividing the 4×2 semiconductor device 110 at each of the isolations 50a and 50d.

Thus, in this embodiment, besides manufacturing the semiconductor device 110, it is possible to manufacture the semiconductor devices 110A to 110E, which are provided with differing numbers of device portions 1 by dividing the substrate 10 using any of the dicing lines DL1 to DL5.

The semiconductor devices 110 and 110A to 110E have an on-resistance that depends on the number of device portions 1. In other words, after using the same mask pattern to form the device portions 1 and electrode portions, devices with differing on-resistance can be easily manufactured by dividing the substrate 10 as required.

Moreover, the first electrode portions and the second electrode portions provided on the respective device portions 1 can be given electrical commonality. As a result, when connecting a connecting member such as a bonding wire or the like, interconnects (including electrode portions) electrically contacted with the respective first electrode portions and second electrode portions need only connect to single point to achieve electrically contacted with all the device portions 1.

Further, in the above-described semiconductor devices 110A to 110E, when the substrate 10 is divided along the dicing lines DL1 to DL5, at least one of the first connecting portion 11, second connecting portion 21 and conducting portion 31 is cut. Consequently, when the substrate 10 is divided, a side face of the dicing saw contacts the first connecting portion 11, the second connecting portion 21 and the conducting portion 31, which are conductors, and static electricity generated by the friction during the cutting can be discharged via the first connecting portion 11, the second connecting portion 21 and the conducting portion 31. As a result, the effects of static electricity in the semiconductor devices 110A to 110E and the dust collecting effect caused by static electricity can be suppressed.

### Second Embodiment

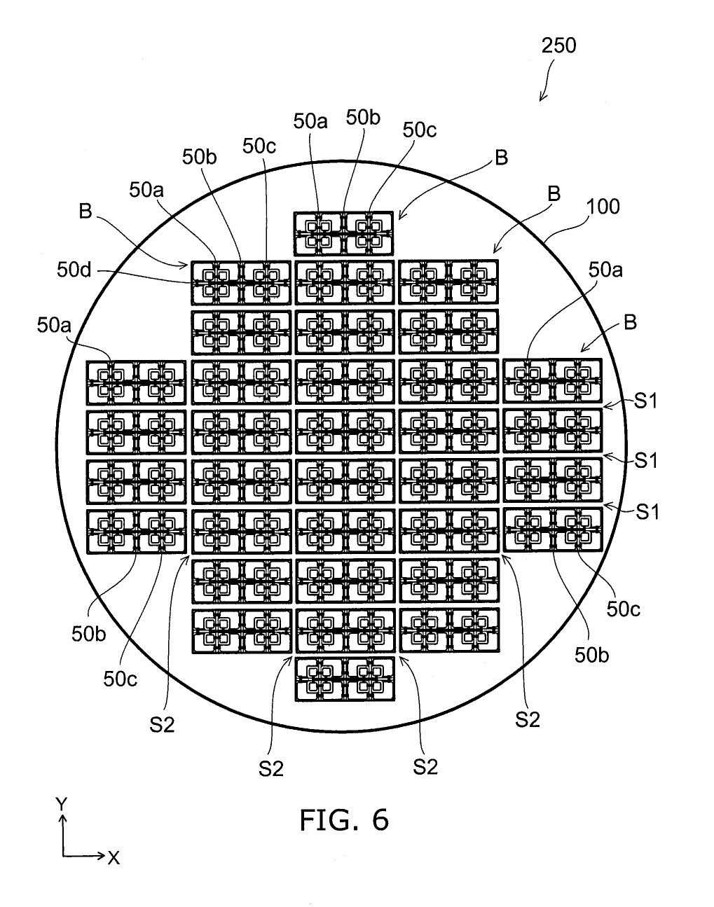

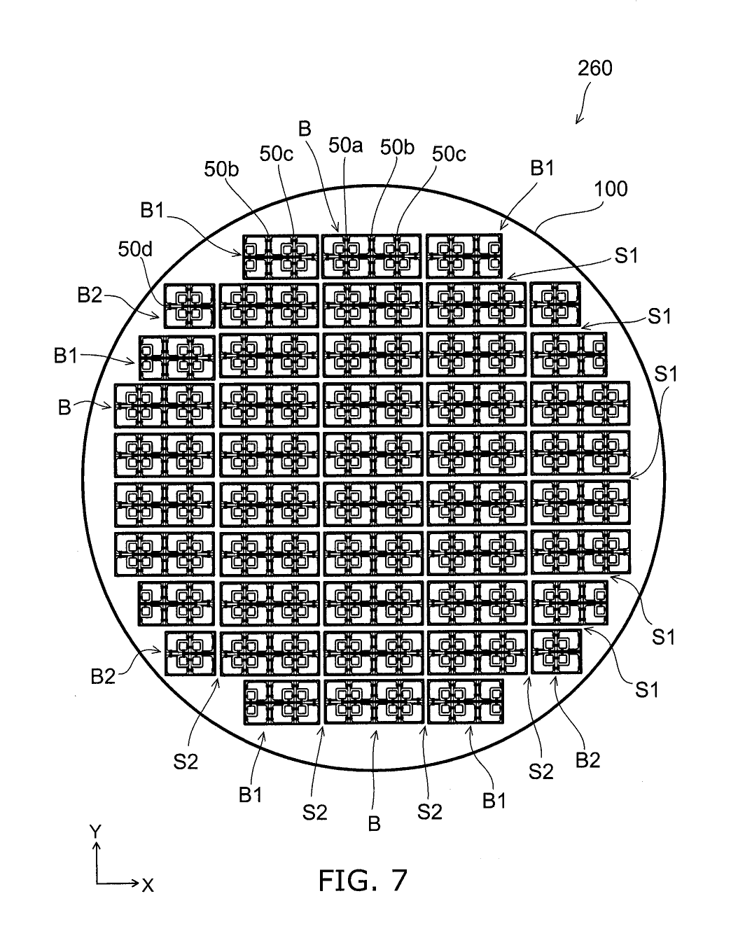

FIG. 6 and FIG. 7 are schematic plan views illustrating semiconductor group members according to a second embodiment.

FIG. 6 and FIG. 7 illustrate semiconductor group members 250 and 260 in a state in which a plurality of device blocks B is formed on a wafer 100.

As illustrated in FIG. 6, the semiconductor group member 250 includes a plurality of device blocks B formed on the wafer 100.

On the wafer 100, the plurality of device blocks B is arranged along an X direction and a Y direction. The plurality of device blocks B is arranged so as to be aligned along the X direction and the Y direction. Hence, isolations S1 are provided linearly along the X direction of the wafer 100 and isolations S2 are provided linearly along the Y direction of the wafer 100.

All of the plurality of device blocks B has the same configuration. The device blocks B illustrated in FIG. 6 have, for example, a configuration including 4×2 device portions 1 identical to the semiconductor device 110 illustrated in FIG. 1A.

Thus, each of the device blocks B includes the plurality of device portions is to 1h provided on the wafer 100, the first electrode portions 10a to 10h provided on the plurality of device portions 1a to 1h, the second electrode portions 20a to 20h provided on the plurality of device portions 1a to 1h, the first connecting portions 11 and the second connecting portion 21.

Further, the plurality of device blocks B each includes the conducting portion 31.

The first electrode portions 10a, 10b, 10e and 10f are positioned near the isolations 50a and 50d.

Further, the first electrode portions 10c, 10d, 10g and 10h are also positioned near the isolations 50c and 50d.

In the semiconductor group member 250, the isolations 50d are linearly aligned along the X direction in the plurality of device blocks B arranged along the X direction. Further, in the plurality of device blocks B arranged along the Y direction, the isolations 50a, 50b and 50c are linearly aligned along the Y direction.

The isolations 50a, 50b, 50c and 50d and the isolations S1 and S2 are selected as necessary for use as dicing lines for the wafer 100. Depending on which isolations from among isolations 50a, 50b, 50c and 50d and isolations S1 and S2 are selected as dicing lines, semiconductor devices of a desired a×b configuration can be formed.

For example, when the wafer 100 is diced along the isolations S1 and S2, the 4×2 semiconductor device 110 illustrated in FIG. 1A is formed.

Further, when the wafer 100 is diced along the isolations S1 and S2 and the isolation 50b, the 2×2 semiconductor device 110A illustrated in FIG. 1B is formed.

Similarly, by selecting from among the isolations 50a, 50b, 50c and 50d and the isolations S1 and S2, various types of product development can be realized, including product development with the 1×2 semiconductor device 110B, the 1×1 semiconductor device 110C, the 3×2 semiconductor device 110D or the 3×1 semiconductor device 110E.

As illustrated in FIG. 7, the semiconductor group member 260 resembles the semiconductor group member 250 in including the plurality of device blocks B formed on the wafer 100 but differs in the configuration of the plurality of device blocks B.

In the semiconductor group member 260, device blocks B including 4×2 device portions 1, device blocks B1 including 3×2 device portions 1 and device blocks B2 including 2×2 device portions 1 are disposed on the wafer 100.

Specifically, the device blocks B including the 4×2 device portions 1 are arranged in a central part of the wafer 100, the device blocks B1 including the 3×2 device portions 1 and the device blocks B2 including the 2×2 device portions 1 are arranged in the regions left open around the device blocks B including the 4×2 device portions 1.

Note that configuration and layout of the a×b device portions 1 are not limited to those of the example illustrated in FIG. 7.

For example, in the semiconductor group member 260 including a plurality of device blocks B, B1 and B2, each with a different configuration, the isolations S1 are aligned linearly along the X direction of the wafer 100 and the isolations S2 are aligned linearly along the Y direction of the wafer 100.

Further, in the plurality device blocks B, B1 and B2 arranged along the X direction, the isolations 50d are linearly aligned along the X direction. Further, in the plurality of device blocks B, B1 and B2 arranged along the Y direction, the isolations 50a, 50b and 50c are linearly aligned along the Y direction.

Depending on which isolations from among isolations 50a, 50b, 50c and 50d and isolations S1 and S2 are selected as dicing lines, semiconductor devices of a desired a×b configuration can be formed.

Through the inclusion of the device blocks B, B1 and B2 with different configuration in the semiconductor group member 260, waste can be suppressed when the wafer 100 is diced and semiconductor devices of various configurations (such as the semiconductor devices 110 and 110A to 110E) can be efficiently manufactured from the single wafer 100.

Note that in the semiconductor group member 250 and 260 according to the second embodiment, the configuration and layout of the a×b device portions 1 of the device blocks are not limited to those illustrated in FIG. 6 and FIG. 7.

### Third Embodiment

Next, a third embodiment will be described. The third embodiment is an example of a manufacturing method for a semiconductor device.

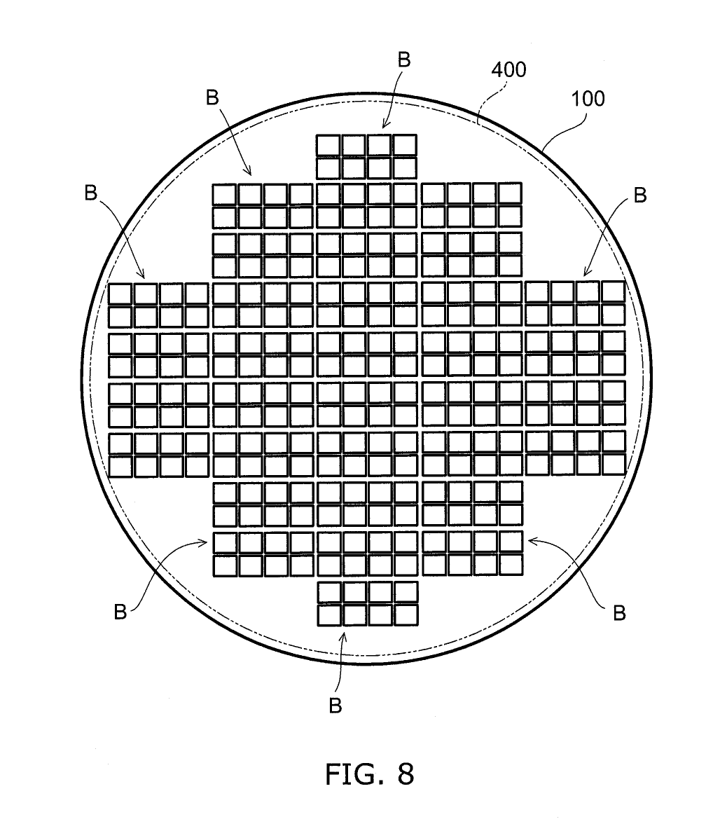

FIG. 8 to FIG. 16 are schematic views illustrating a manufacturing method according to the third embodiment.

First, a plurality of device portions 1 is formed on the wafer 100 as illustrated in FIG. 8. Isolations are provided between the device portions 1. In FIG. 8, as an example, a plurality of device blocks B, each having a set of 4×2 device portions 1 (device block B), is formed on the wafer 100.

After forming the device blocks B, a conducting film 400 is formed uniformly on a surface of the wafer 100.

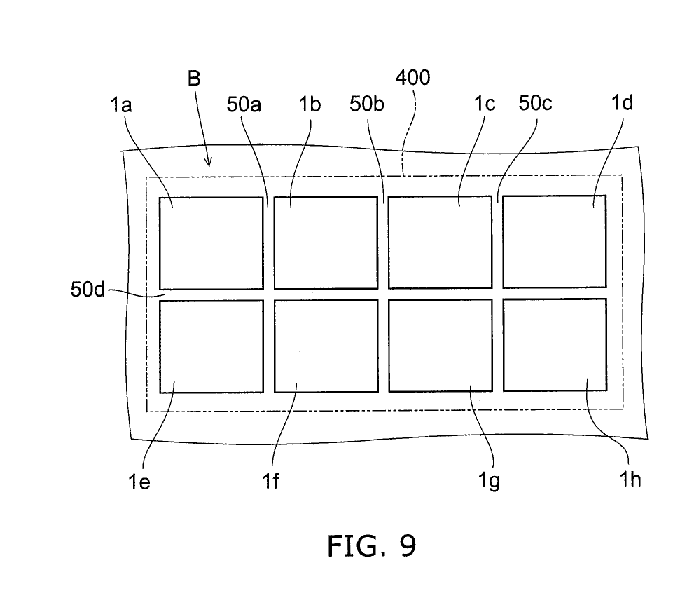

FIG. 9 is a magnified schematic plan view of a set of device units having a plurality of device portions.

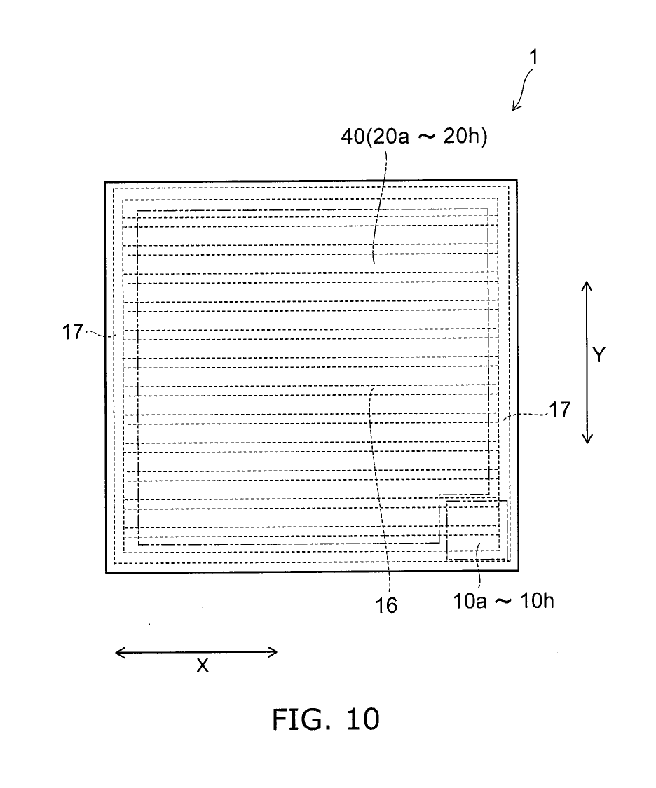

FIG. 10 is a magnified schematic plan view of one of the device portions.

As illustrated in FIG. 9, a single device block B has, for example, 4×2 device portions 1 formed therein. The isolations 50a to 50d are provided between the device portions 1a to 1h. The device portions 1 are provided with a predetermined function using predetermined photolithography, impurity implantation and the like. The conducting film 400 is provided uniformly on the device portions 1.

FIG. 10 is a schematic plan view of a case when a MOSFET is formed in the device portion.

As illustrated in FIG. 10, a plurality of gate electrodes 16 is formed so as to extend in the X direction. A gate interconnect 17 extends in the Y direction that is perpendicular to the X direction. The gate interconnect 17 is, for example, provided in a ring form, and electrically contacted with the plurality of gate electrodes 16.

The gate electrodes 16 are formed by, for example, a Chemical Vapor Deposition (CVD) method in which polycrystalline silicon is embedded in trenches. The gate interconnect 17 is also formed at this time by further forming polycrystalline silicon at portions where the gate interconnects are to be formed on the surface of the semiconductor layer above the trench opening edges.

An insulating layer not illustrated in the drawings is provided on the gate electrodes 16. An opening is provided in the insulating layer over a source region to enable electrically contact with a first main electrode 40, which is formed later. Further, an opening is also formed in the insulating layer over the gate interconnect 17 to enable electrically contact with the first electrode portions 10a to 10h, which are formed later.

In the MOSFET, the first main electrode 40 functions as a source electrode. The first main electrode 40 is connected to the second electrode portions 20a to 20h. Note that the first main electrode 40 may also function as the second electrode portions 20a to 20h.

A second main electrode not illustrated in the drawings is formed on the back face of the wafer 100. The second main electrode functions as a drain electrode.

The first electrode portions 10a to 10h and the second electrode portions 20a to 20h are formed by patterning a conducting layer 400 (see FIG. 9) that is formed uniformly on the insulating layer.

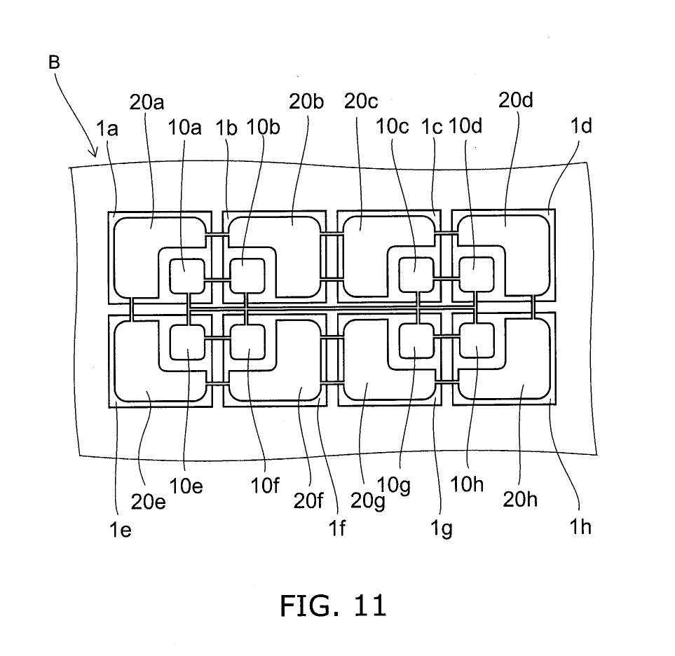

FIG. 11 is a schematic plan view illustrating a state after patterning of a conducting layer.

FIG. 11 illustrates a pattern of a single device block B. When the conducting layer is patterned, the first electrode portions 10a to 10h, the second electrode portions 20a to 20h, the first connecting portions 11, the second connecting portions 21 and the conducting portion 31 are formed. The first connecting portions 11 and the second connecting portions 21 are formed so as to bridge the isolations 50a to 50d. The conducting portion 31 is formed along the isolation 50d.

After the pattering of the conducting layer, a protective film is formed over the first electrode portions 10a to 10h, the second electrode portions 20a to 20h, the first connecting portions 11, the second connecting portions 21, and the conducting portion 31. The protective film may, for example, be formed using a polyimide.

Next, the wafer 100 is divided to desired sizes. As described previously, the wafer 100 is diced using dicing lines corresponding to a×b configurations. In this embodiment, the processes up to the dicing of the wafer 100 are the same irrespective of the a×b configuration. In other words, the mask pattern can be the same until the dicing process.

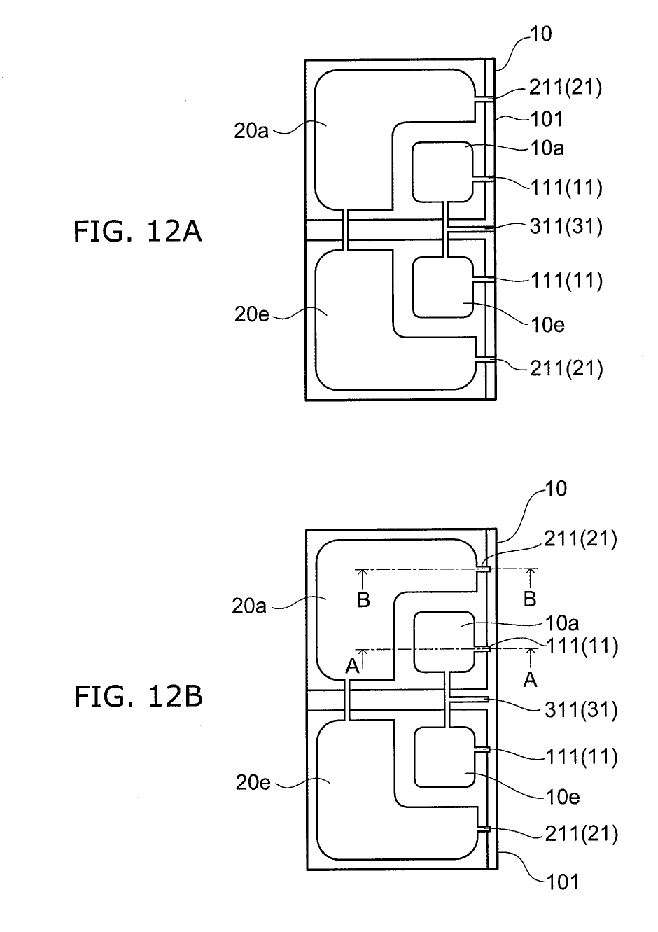

FIGS. 12A and 12B are schematic plan views illustrating a state after division into 1×2 configurations.

Depending on the a×b configuration, the first connecting portions 11, the second connecting portions 21 and the conducting portion 31 may be cut partway along. For the 1×2 configuration illustrated in FIG. 12, the wafer 100 is divided with the isolation 50a as the dicing line, and consequently, the first connecting portions 11, the second connecting portions 21 and the conducting portion 31 are cut partway along to form the protruding portions 111, 211 and 311, respectively.

As illustrated in FIG. 12A, the protruding portions 111, 211 and 311 are formed at the peripheries 101 of the substrate 10 which are obtained when the wafer 100 is cut into rectangular forms. As illustrated in FIG. 12B, after dicing the wafer 100, end portions of the protruding portions 111, 211 and 311 exposed at the peripheries 101 of the substrate 10 are caused to recede. For example, by etching the metal which forms the protruding portions 111, 211 and 311, the end portions are caused to recede to an inner side of the periphery 101 of the substrate 10.

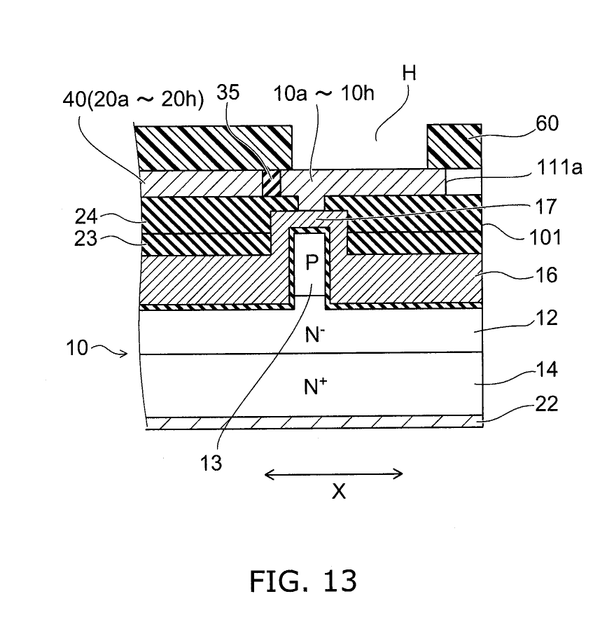

FIG. 13 is a schematic cross-sectional view in the direction of the arrows at the line A-A in FIG. 12B.

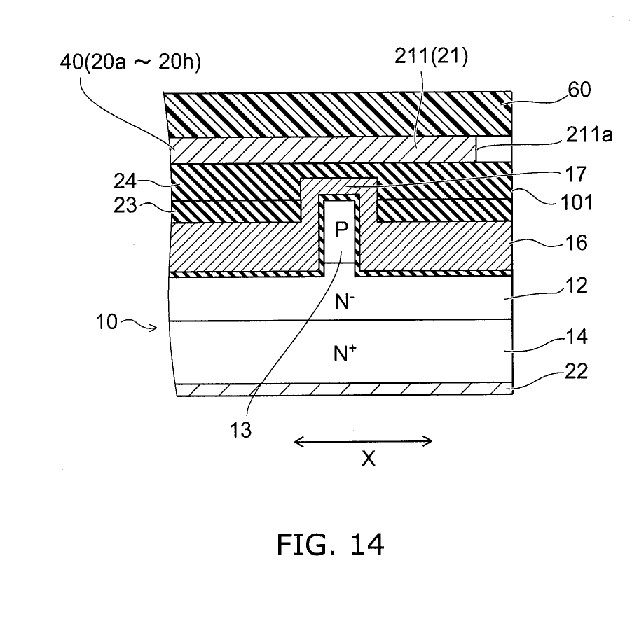

FIG. 14 is a schematic cross-sectional view in the direction of the arrows at the line B-B in FIG. 12B.

As illustrated in FIG. 13, an n⁺-type drain layer 14, an n⁻-type drift layer 12, and a p-type base region 13 are provided on the substrate 10 and a second main electrode 22 that is a drain electrode is provided on a back face of the substrate 10.

Insulating layers 23 and 24 are provided on the gate electrode 16, and the insulating layers 23 and 24 serve to separate the gate electrode 16 and first main electrode 40.

The first main electrode 40 and the first electrode portions 10a to 10h are formed on the insulating layer 24. The first main electrode 40 and the first electrode portions 10a to 10h are separated by the insulating layer 35 on the insulating layer 24.

The first electrode portions 10a to 10h are connected to the gate electrode 16 via an opening provided in the insulating layer 24.

A protective film 60 is formed on the first main electrode 40 and the first electrode portions 10a to 10h. An opening H is provided in a portion of the protective film 60 to allow bonding wire or the like to be connected to the first electrode portions 10a to 10h that are exposed through the opening H.

A portion that protrudes outwards from the first electrode portions 10a to 10h between the insulating layer 24 and the protective film 60 is the protruding portion 111. An end portion 111a of the protruding portion 111 has receded to an inner side of the periphery 101 of the substrate 10. When the end portion 111a of the protruding portion 111 is etched, the insulating layer 24 and the protective film 60 are not etched. As a result, only the end portion 111a of the protruding portion 111 has receded to a position inward of the periphery 101 of the substrate 10.

As illustrated in FIG. 14, the portion of the second electrode portions 20a to 20h that functions as the first main electrode 40 is provided on the insulating layer 24. The second electrode portions 20a to 20h are provided between the protective film 60 and the insulating layer 24. The portion that protrudes outwards from the second electrode portions 20a to 20h between the insulating layer 24 and the protective film 60 is the protruding portion 211. An end portion 211a of the protruding portions 211 has receded to an inner side of the periphery 101 of the substrate 10. In the same way as described above, when the end portion 211a of the protruding portion 211 is etched, the insulating layer 24 and the protective film 60 are not etched. Hence, only the end portion 211a has receded to a position inward of the periphery 101 of the substrate 10.

Thus, by having the end portions 111a and 211a of the protruding portions 111 and 211 receding inward of the periphery 101 of the substrate 10, exposure of the end portions 111a and 211a of the protruding portions 111 and 211, which are conductors, can be prevented.

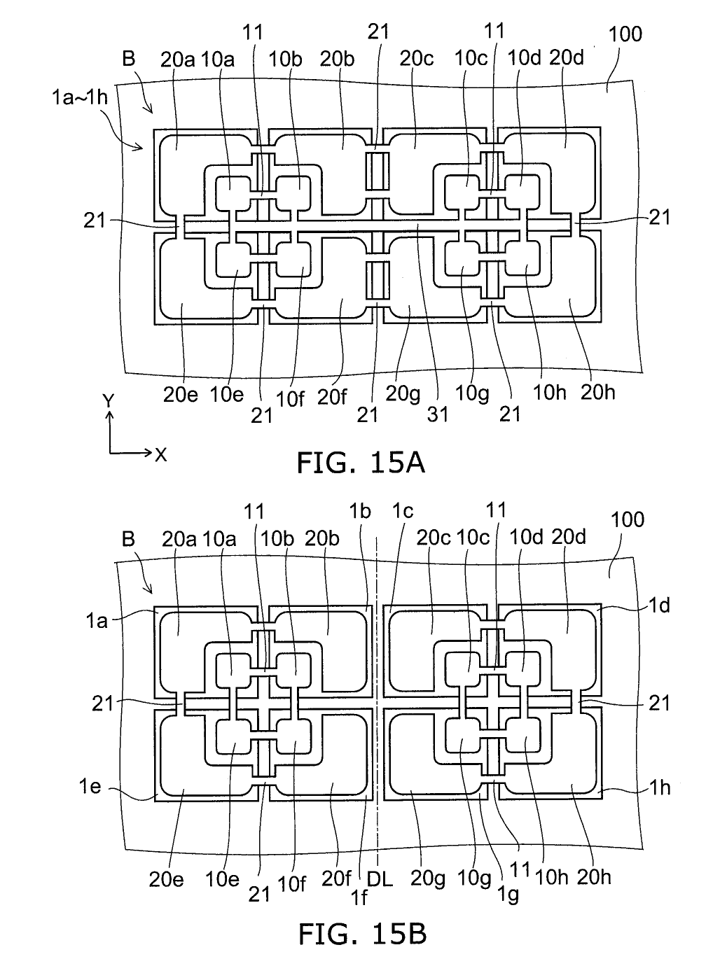

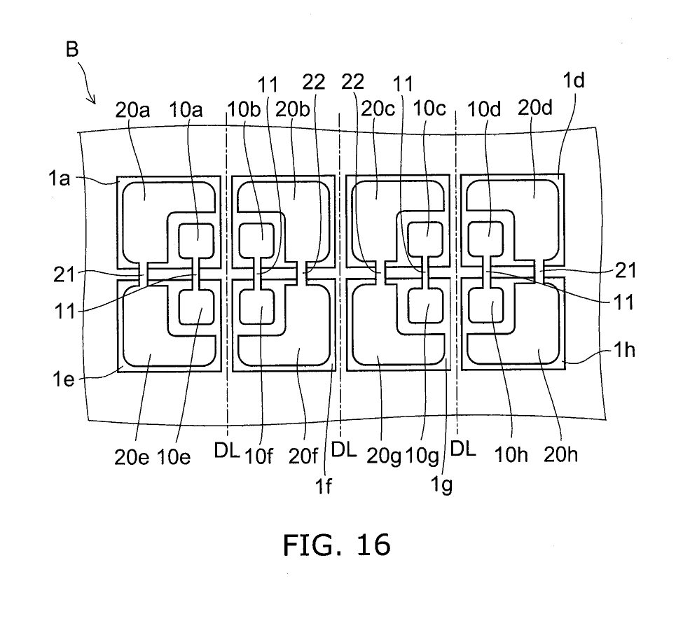

FIG. 15A to 16 are schematic plan views illustrating of another manufacturing method.

The other manufacturing method is identical to the previously described manufacturing method up to the forming of the conducting layer 400 on a plurality of device blocks B with the device portions 1 formed on the wafer 100.

In the other manufacturing method, after forming the conducting layer 400, the conducting layer 400 is patterned according to the a×b configuration of the device portions 1 that are to be obtained by cutting the wafer 100, and the first electrode portions 10a to 10h, the second electrode portions 20a to 20h, the first connecting portions 11, the second connecting portions 21 and the conducting portions 31 are formed according to the a×b configuration.

As a result, the same mask pattern can be used for processes up to the forming of the plurality of device portions 1 on the wafer 100.

In the case that the semiconductor device is configured with 4×2 device portions 1 as illustrated in FIG. 15A, a mask pattern to form the first connecting portions 11 that connect the first electrode portions 10a, 10b, 10e and 10f and the first connecting portions 11 that connect the first electrode portions 10c, 10d, 10g and 10h, the conducting portion 31 that connects the first electrode portions 10a, 10b, 10e and 10f, the first electrode portions 10c, 10d, 10g and 10h, and the second connecting portions 21 that connect the second electrode portions 20a to 20h is used.

Then, the semiconductor devices are formed by cutting each of the 4×2 device portions 1 from the wafer 100.

In the case that the semiconductor device is configured with 2×2 device portions 1 as illustrated in FIG. 15B, for the device portions 1a, 1b 1e and 1f, a mask pattern to form the first connecting portions 11 that connect the first electrode portions 10a, 10b, 10e and 10f and the second connecting portions 21 that connect the second electrode portions 20a, 20b, 20e and 20f is used.

For the device portions 1c, 1d, 1g and 1h, a mask pattern to form the first connecting portions 11 that connect the first electrode portions 10c, 10d, 10f and 10h and the second connecting portions 21 that connect the second electrode portions 20c, 20d, 20g and 20h is used.

Then, the semiconductor devices are formed by cutting each of the 2×2 device portions 1 from the wafer 100. Here, because there is no conductor such as a metal or the like at the dicing lines DL, conductors are not exposed at the cut faces of the wafer 100.

In the case that the semiconductor device is configured with 1×2 device portions 1 as illustrated in FIG. 16, for the device portions 1a and 1e, a mask pattern to form the first connecting portion 11 that connects the first electrode portions 10a and 10e and the second connecting portion 21 that connects the second electrode portions 20a and 20e is used.

The same applies for the device portions 1b and 1f, the device portions 1c and 1g, and the device portions 1d and 1h.

Then, the semiconductor devices are formed by cutting each of the 1×2 device portions 1 from the wafer 100. Because there is no conductor such as a metal at the dicing lines DL, no conductor is exposed at the cut faces of the wafer 100.

In the other manufacturing method of this type, the processes up to the formation of the plurality of device portions are shared with the previously described manufacturing method, and various electrode portion forms can subsequently be formed by patterning the conducting film 400.

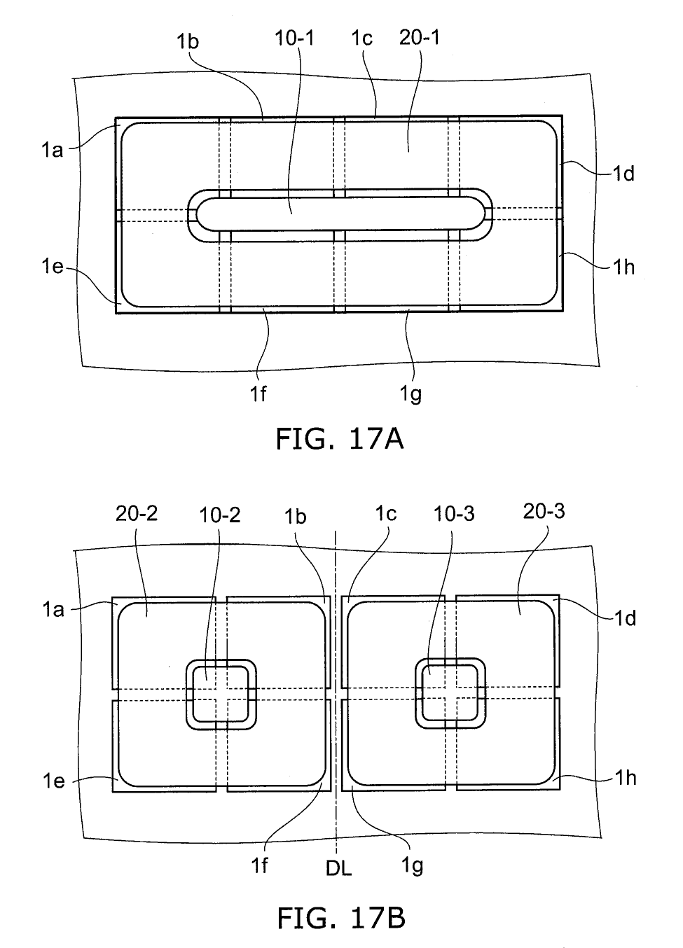

FIGS. 17A and 17B are schematic plan views illustrating a form of electrode portions.

As illustrated in FIG. 17A, when a semiconductor device is configured with the 4×2 device portions 1, a mask pattern to form a first electrode portion 10-1 and a second electrode portion 20-1 common to the device portions is to 1h is used. The first electrode portion 10-1 is formed at a center portion of the 4×2 device portions 1, bridging between the device portions 1a to 1h. The second electrode portion 20-1 is formed surrounding the first electrode portion 10-1, bridging between the device portions 1a to 1h.

In the case that the semiconductor device is configured with 2×2 device portions 1 as illustrated in FIG. 17B, a mask pattern to form a first electrode portion 10-2 and a second electrode portion 20-2 common to the device portions 1a, 1b 1e and 1f and a first electrode portion 10-3 and a second electrode portion 20-3 common to the device portions 1c, 1d, 1g and 1h is used.

The first electrode portion 10-2 is formed at a center portion of the 2×2 device portions 1 with the device portions 1a, 1b, 1e and 1f, bridging between the device portions 1a, 1b 1e and 1f. The second electrode portion 20-2 is formed surrounding the first electrode portion 10-2, bridging between the device portions 1a, 1b, 1e and 1f.

The first electrode portion 10-3 is formed at a center portion of the 2×2 device portions 1 with the device portions 1c, 1d, 1g and 1h, bridging between the device portions 1c, 1d, 1g and 1h. The second electrode portion 20-3 is formed surrounding the first electrode portion 10-3, bridging between the device portions 1c, 1d, 1g and 1h.

Due to the presence of the first electrode portion 10-1, 10-2 and 10-3 and the second electrode portions 20-1, 20-2 and 20-3, the plurality of device portions 1 can be connected by the common first electrode portions 10-1, 10-2 and 10-3 and second electrode portions 20-1, 20-2 and 20-3. In other words, the first electrode portions 10-1, 10-2 and 10-3 and the second electrode portions 20-1, 20-2 and 20-3 can also function as the first connecting portions 11, the second connecting portions 21 and the conducting portion 31. As a result, the conductor can be made wider than when the first connecting portions 11, the second connecting portions 21 and the conducting portion 31 are provided separately, thus reducing the resistance of the first electrode portions 10-1, 10-2 and 10-3 and second electrode portions 20-1, 20-2 and 20-3 bridging between the device portions 1.

Note that the form of the first electrode portions 10-1, 10-2 and 10-3 and the second electrode portions 20-1, 20-2 and 20-3 is not limited to that illustrated in FIG. 17 and a form appropriately matched to the a×b configuration of the device portions can be used.

### Fourth Embodiment

Next, a fourth embodiment will be described. The fourth embodiment is an example of a manufacturing method for a semiconductor device.

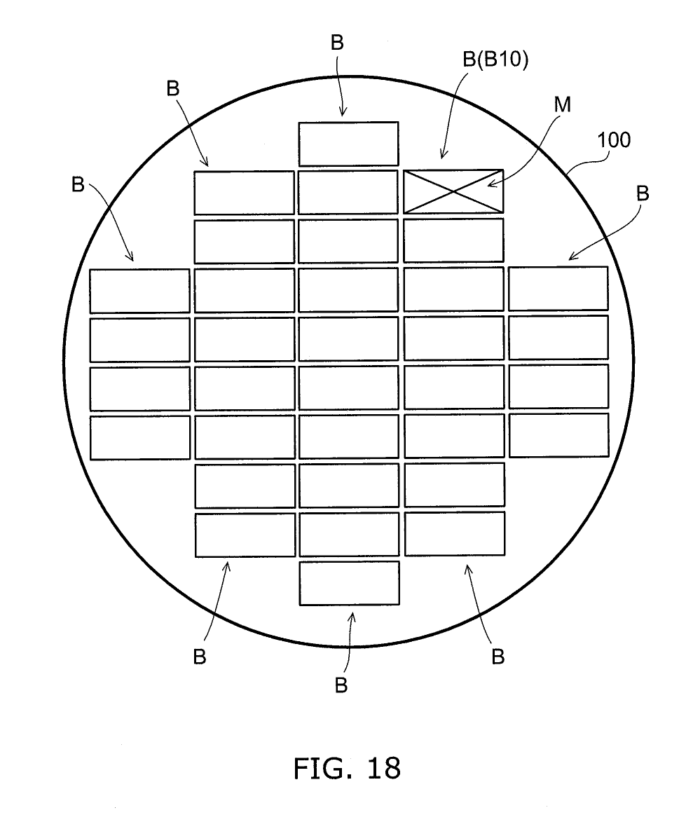

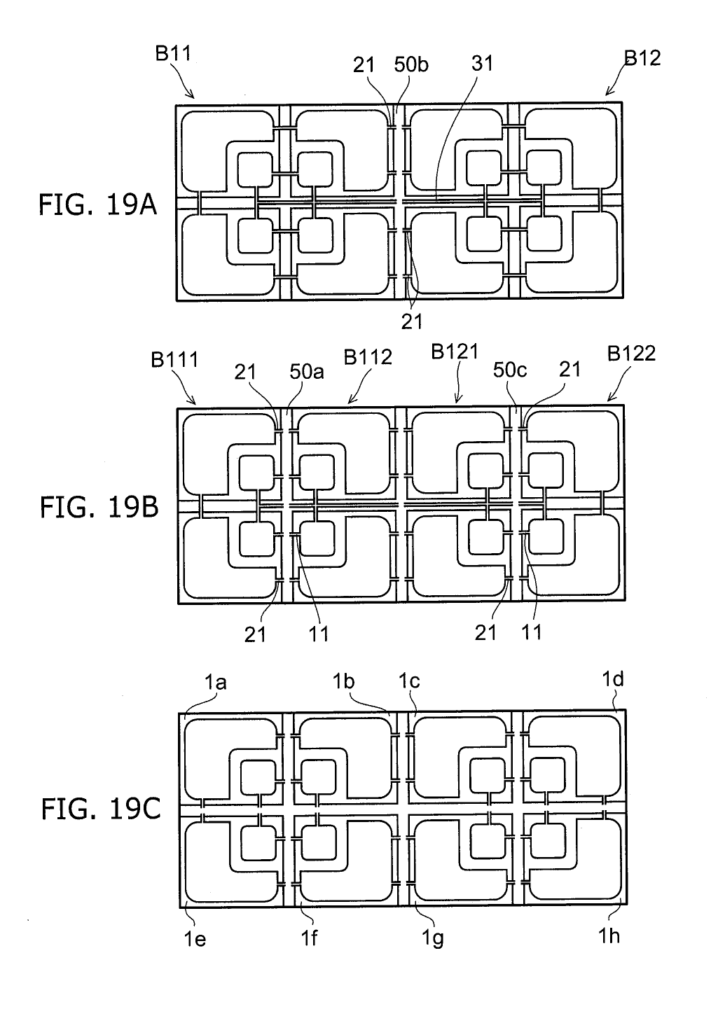

FIG. 18 to FIG. 19C are schematic plan views illustrating a manufacturing method according to the fourth embodiment.

The manufacturing method according to the fourth embodiment is the same as the manufacturing method of the third embodiment up to the forming of the plurality of device blocks B on the wafer 100. In this embodiment, a plurality of device blocks B with, for example, 4×2 device portions 1 is formed. The device blocks B have formed therein the first electrode portions 10a to 10h, the second electrode portions 20a to 20h, the first connecting portions 11, the second connecting portions 21 and the conducting portion 31 illustrated in FIG. 1.

In FIG. 18, the device blocks B formed on the wafer 100 are illustrated as rectangular frames for ease of explanation. After forming the device blocks B, predetermined electrical testing is performed on the device block B units on the wafer 100. The electrical testing involves causing a probe that is not illustrated in the drawings to contact the wafer 100 and testing electrical continuity and characteristics. When a given device block B does not meet predefined tolerances in the testing, a mark M is added to that device block B in the test data. For example, if a proportion or distribution of device portions 1 that have the predetermined characteristics in a device block B is not satisfied, that device block B is marked with the mark M. In FIG. 18, the device block B10 is marked with the mark M.

Here, the device blocks B that meet the predefined tolerances in the testing are divided from the wafer 100 in 4×2 blocks and used as semiconductor devices. Note that the 4×2 configuration may be further divided to form semiconductor device of other sizes, such as 2×2, 3×1, and 1×1.

On the other hand, for the device block B10 which does not meet the predefined tolerances in the testing, the second connecting portions 21 and the conducting portion 31 that bridge the isolation 50b are cut as illustrated in FIG. 19A. To cut the second connecting portions 21 and the conducting portion 31, the wafer 100 is, for example, half-diced at the isolation 50b.

Note that another method is possible whereby, for example, a large current is passed through both ends of the second connecting portions 21 and the conducting portion 31 which are to be cut, and the cut is made using the resulting joule heat. When the method whereby the second connecting portions 21 and the conducting portion 31 are to be cut using a large current is used, a more effective cut is possible if a portion of each of the second connecting portions 21 and the conducting portion 31 is made narrower.

By cutting the second connecting portions 21 and the conducting portion 31 in this way, it is possible to separate regions of electrical continuity within the device block B10 and retest electrical characteristics in each region.

After cutting the second connecting portions 21 and the conducting portion 31, electrical characteristics of the 2×2 device blocks B11 and B12 are tested. If the device blocks B11 and B12 meet the predefined tolerances in the testing, the wafer 100 is diced at the isolation 50b to form the semiconductor device with the 2×2 device blocks B11 and B12.

On the other hand, if one of the device blocks B11 and B12 fails to meet the predefined tolerances, the first connecting portions 11, second connecting portions 21 and conducting portion 31 that bridge the isolations provided at a center of the device block that failed to meet the tolerances are cut. FIG. 19B illustrates a case in which both the device blocks B11 and B12 failed to meet the tolerances. In this case, the first connecting portions 11, the second connecting portions 21 and the conducting portion 31 bridging the isolations 50a and 50c are cut.

After cutting the first connecting portions 11, the second connecting portions 21 and the conducting portion 31, electrical characteristics of the 1×2 device blocks are tested. In the example illustrated in FIG. 19B, the 1×2 device blocks B111, B112, B121, and 8122 are each tested. If the predefined tolerances are met, dicing is performed along the isolations 50a, 50b and 50c to cut apart the device blocks B111, B112, B121, and B122 that have met the tolerances. Semiconductor devices with 1×2 device blocks are thereby formed.

On the other hand, if one of the device blocks 6111 and B112, B121 and B122 fails to meet the predefined tolerances, the first connecting portions 11, the second connecting portions 21 and the conducting portion 31 that bridge the isolation 50d provided at a center of the device block that failed to meet the tolerances are cut. FIG. 19C illustrates a case in which all of the device blocks B111, B112, 8121, and B122 failed to meet the tolerances. By dicing the wafer 100 along the isolation 50d, semiconductor devices with the 1×1 device portions 1a to 1h are formed.

Electrical characteristics of each of the 1×1 device portions 1a to 1h are then tested and only those that meet the predefined tolerances are selected.

Thus, when there is a device block that does not meet the tolerances, the device block is sequentially divided and retested, thus allowing all devices that meet the tolerances to be used and preventing wasted. Specifically, when the 4×2 device block B meets the tolerances, the 4×2 device block B can be used as a semiconductor device. When the 4×2 device block B fails to meet the tolerances, the block is sequentially divided until the tolerances are met, thus making it possible to efficiently form semiconductor devices using the device portions that meet the tolerances.

Note that although in the above description the device block that failed to meet the tolerance was successively halved, this is no more than an example. For example, when the 4×2 device block B1 that fails to meet the tolerance is divided, the division may be performed using the isolation 50a or the isolation 50c to form a 1×2 device block and a 3×2 device block. Alternatively, the division may be performed using the isolation 50d to form a 4×1 device block.

### Fifth Embodiment

Next, a fifth embodiment will be described. The fifth embodiment is an example of a semiconductor device included in a package.

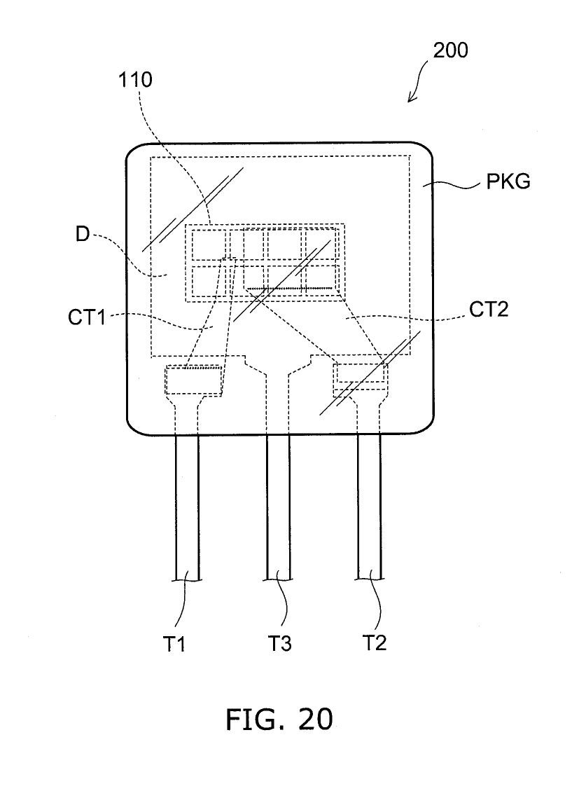

FIG. 20 is a schematic plan view illustrating a semiconductor module that is an example of the semiconductor device according to the fifth embodiment.

As illustrated in FIG. 20, a semiconductor module 200 includes the semiconductor devices 110 and 110A to 110E described previously, at least two external terminals and a sealing member PKG that forms the package.

As an example, the semiconductor module 200 illustrated in FIG. 20 is an application of the semiconductor device 110 illustrated in FIG. 1. When the device portions 1 of the semiconductor device 110 are MOSFETs, three external terminals T1 to T3 are provided.

At least one of the first electrode portions 10a to 10h of the semiconductor device 110 and the external terminal T1 are connected by a first connecting member CT1. Further, at least one of the second electrode portions 20a to 20h of the semiconductor device 110 and the external terminal T2 are connected by a second connecting member CT2. The external terminal T3 is integrated with a seating portion D for mounting the semiconductor device 110. By mounting the semiconductor device 110 on the seating portion D, the electrode on the back face of the semiconductor device 110 (the second main electrode 22 in FIGS. 13 and 14) is electrically contacted with the external terminal T3 via the seating portion D.

The first connecting member CT1 and the second connecting member CT2 are, for example, formed using metal plate. When metal plate is used to form the first connecting member CT1 and the second connecting member CT2, the electrode portions and external terminals are bonded using, for example, solder.

The sealing member PKG is, for example, a molded resin. The sealing member PKG seals a portion of the external terminals T1 to T3, the first connecting member CT1, the second connecting member CT2 and the semiconductor device 110. The three external terminals T1 to T3 protrude outwards from the sealing member PKG. When the device portion 1 is a MOSFET, the external terminal T1 is, for example, a gate terminal electrically contacted with the gate electrode, the external terminal T2 is, for example, a source terminal electrically contacted with the source electrode and the external terminal T3 is, for example, a drain terminal electrically contacted with the drain electrode.

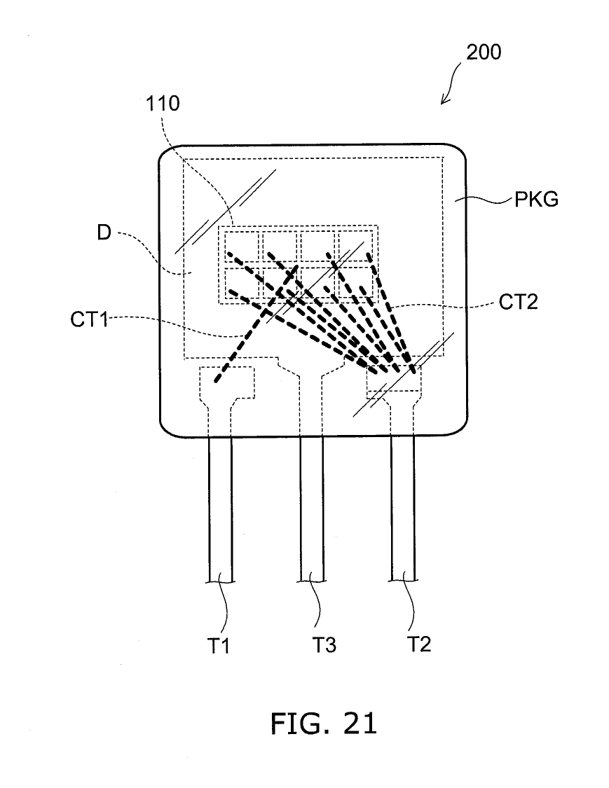

FIG. 21 is a schematic plan view for describing another example of the connecting member.

In the semiconductor module 200 illustrated in FIG. 21, the first connecting member CT1 and the second connecting member CT2 are bonding wire.

When bonding wire is used, the degree of freedom in connection position is high. For example, the first connecting member CT1 that provides electrical continuity between the external terminal T1 and the first electrode portions 10a to 10h is preferably connected to an approximate center of the conducting portion 31 that connects the first electrode portions 10a to 10h. When the first connecting member CT1 is connected at the approximate center, signals input from the first external terminal T1 are transmitted uniformly to the first electrode portions 10a to 10h. Hence, signal delays among the first electrode portions 10a to 10h can be suppressed.

Further, when bonding wire is used, a plurality of bonding wires for a plurality of electrode portions may be connected from a single external terminal T1 or T2. For example, for the connection between the second external terminal T2 and the second electrode portions 20a to 20h, bonding wires may be connected from the second external terminal T2 to each of the second electrode portions 20a to 20h. When the second electrode portions 20a to 20h are electrically contacted with, for example, a source electrode, a large current can be supported by connecting a plurality of bonding wires.

Note that although an example in which the semiconductor device 110 was used in the semiconductor modules 200 illustrated in FIG. 20 and FIG. 21, the other semiconductor devices 110A to 110E may also be used.

As described above, according to this embodiment, a common mask pattern can be used when forming the device portions 1, and devices with different on-resistance can be easily formed by changing cutting positions on the wafer 100.

Note that although in the embodiments and variations described above were described in which the device portions were mainly MOSFETs, the device portions 1 are not limited to being MOSFETs and may, for example, be mixture of devices such as IGBTs, diodes, MOSFETs and Schottky Barrier Diode (SBDs), or the like. The semiconductor device 110 having a configuration of 4×2 device portions 1 was described as example, but the invention may be applied to an a×b configuration larger than 4×2.

The above has described embodiments and variations on these embodiments, but the invention is not limited to these. Any configuration of above the described embodiments or variations which has been added to, removed from, or changed in design in a way that could be easily arrived at by a person skilled in the art, and any appropriate combination of the characteristics of the embodiments is also to be construed as being within the scope of the invention.

As described above, according to the semiconductor device and the manufacturing method of the embodiments, devices of various on-resistances can be easily manufactured.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a device portion provided on a substrate;
a first electrode portion provided on the device portion and electrically contacted with the device portion;
a second electrode portion provided on the device portion separated from the first electrode portion, and electrically contacted with the device portion; and
a protruding portion provided on the device portion and protruding outward from a peripheral portion of the first electrode portion and the second electrode portion.

2. A semiconductor device ,comprising:
a plurality of device portions provided on a substrate;
a first electrode portion provided on each of the plurality of device portions, and electrically contacted with each of the plurality of device portions;
a second electrode portion provided on each of the plurality of device portions separated from the first electrode portion, and electrically contacted with each of the plurality of device portions;
a first connecting portion bridging a isolation provided between the adjacent device portions and connecting the first electrode portion to another adjacent first electrode portion; and
a second connecting portion bridging the isolation and connecting the adjacent second electrode portions.

3. The device according to claim 2, further comprising a protruding portion protruding outward from a peripheral portion of the first electrode portion and a peripheral portion of the second electrode portion.

4. The device according to claim 3, wherein an end of the protruding portion is positioned inward of a periphery of the substrate.

5. The device according to claim 2, wherein
at least two of the device portions are provided along each of a first direction along a major surface of the substrate, and a second direction perpendicular to the first direction, and
the first connecting portion further includes a conducting portion electrically connecting the first electrode portion to the another adjacent first electrode portion.

6. The device according to claim 5, wherein the conducting portion is provided along the isolation.

7. The device according to claim 5, wherein, in the four device portions arranged with two of the device portions along each of the first direction and the second direction, the first electrode portion provided on each of the four device portions is positioned near a first isolation along the first direction and a second isolation along the second direction, the first isolation and the second isolation being provided between the four device portions.

8. A semiconductor group member comprising:
a plurality of device blocks formed on a wafer,
each of the plurality of device blocks including:
a plurality of device portions provided on the wafer;
a first electrode portion provided on each of the plurality of device portions, and electrically contacted with each of the plurality of device portions;
a second electrode portion provided on each of the plurality of device portions separated from the first electrode portion, and electrically contacted with each of the plurality of device portions;
a first connecting portion bridging a isolation provided between the adjacent device portions and connecting the first electrode portion to another adjacent first electrode portion; and
a second connecting portion bridging the isolation and connecting the second electrode portion to another adjacent second electrode portion.

9. The member according to claim 8, wherein
at least two of the device portions are provided along each of a first direction of the wafer, and a second direction perpendicular to the first direction, and
the first connecting portion further includes a conducting portion that electrically connects the first electrode portions provided on each of the device portions.

10. The member according to claim 9, wherein the conducting portion is provided along the isolation.

11. The member according to claim 9, wherein, in the four device portions arranged with two of the device portions along each of the first direction and the second direction,, each of the first electrode portions provided on each of the device portions being adjacent along the first direction and the second direction is positioned near a side of the isolation between the device portions being adjacent to each other.

12. The member according to claim 8, wherein, in the plurality of device blocks, a number of the device portions included in each of the device blocks is the same.

13. The member according to claim 8, wherein, in the plurality of device blocks, a number of the device portions included in each of the device blocks is different.

14. The device according to claim 1 further comprising:
a first external terminal;
a second external terminal;
a first connecting member connecting the first external terminal and the first electrode portion;
a second connecting member connecting the second external terminal and the second electrode portion; and
a sealing member configured to seal a portion of the first external terminal, a portion of the second external terminal, the first connecting member, the second connecting member, the substrate, the device portion, the first electrode portion, the second electrode portion, and the protruding portion.

15. The device according to claim 2, further comprising:
a first external terminal;
a second external terminal;
a first connecting member connecting the first external terminal and at least one of the plurality of first electrode portions;
a second connecting member t connecting the second external terminal and at least one of the plurality of second electrode portions; and
a sealing member configured to seal a portion of the first external terminal, a portion of the second external terminal, the first connecting member, the second connecting member, the substrate, the device portions, the first electrode portions, the second electrode portions, and the protruding portion.

16. The device according to claim 15, wherein each of the device portions is a Metal Oxide Semiconductor Field Effect Transistor (MOSFET).

17. The device according to claim 15, wherein each of the device portions is an Insulated Gate Bipolar Transistor (IGBT).

18. A method for manufacturing a semiconductor device, the method comprising:
forming a plurality of device portions on a wafer;
forming, on each of the plurality of device portions, a first electrode portion electrically contacted with each of the plurality of device portions, a second electrode portion separated from the first electrode portion and electrically contacted with each of the plurality of device portions, a first connecting portion bridging a isolation between the adjacent device portions and connecting the first electrode portion to another adjacent first electrode portion, and a second connecting portion bridging the isolation and connecting the second electrode portion to another adjacent second electrode portion;
cutting the wafer along the isolation, and cutting partway the first connecting portion bridging the isolation and the second connecting portion bridging the isolation; and
etching an end of the first connecting portion formed by the cutting and an end of the second connecting portion formed by the cutting to cause the end of the first connecting portion and the end of the second connecting portion to recede from a cut face of the wafer.

19. A method for manufacturing a semiconductor device, the method comprising:
forming a plurality of device portions on a wafer;
forming, on each of the plurality of device portions, a first electrode portion electrically contacted with each of the plurality of device portions, a second electrode portion separated from the first electrode portion and electrically contacted with each of the plurality of device portions, a first connecting portion bridging a isolation between adjacent device portions and connecting the first electrode portion to another adjacent first electrode portion, and a second connecting portion bridging the isolation and connecting the second electrode portion to another adjacent second electrode portion;
evaluating characteristics of the plurality of device portions in a device block unit including a part of the plurality of device portions, dividing the wafer according to the device block unit when a predefined tolerance is satisfied in the device block unit, and dividing the wafer along the isolation within the device block when the tolerance is not satisfied in the device block unit.
